(19) United States
(12) Patent Application Publication
(10) Pub. No.: US 2016/0233352 A1
(43) Pub. Date: Aug. 11, 2016

(54) PHOTOVOLTAIC ELECTRODE DESIGN WITH CONTACT PADS FOR CASCADED APPLICATION

(71) Applicant: SolarCity Corporation, San Mateo, CA (US)

(72) Inventors: Bobby Yang, Los Altos Hills, CA (US); Peter P. Nguyen, San Jose, CA (US)

(73) Assignee: SOLARCITY CORPORATION, San Mateo, CA (US)

(21) Appl. No.: 14/831,767

(22) Filed: Aug. 20, 2015

Related U.S. Application Data
(60) Provisional application No. 62/088,509, filed on Dec. 5, 2014.
(60) Provisional application No. 62/143,694, filed on Apr. 6, 2015.

(51) Int. Cl. H01L 31/0224; H01L 31/0352; H01L 31/0443; H01L 31/02

(52) U.S. Cl. CPC H01L 31/022433; H01L 31/0201; H01L 31/02013; H01L 31/035281; H01L 31/0443

(57) ABSTRACT

An electrode grid design of a photovoltaic structure is provided. The grid can include a plurality of finger lines, an edge busbar positioned near an edge of the photovoltaic structure, and a plurality of contact pads, wherein a respective contact pad is configured in such a way that, when the photovoltaic structure is cascaded with an adjacent photovoltaic structure at the edge, the contact pad is at least partially exposed.

### CROSS-REFERENCE TO OTHER APPLICATIONS

This claims the benefit of U.S. Provisional Patent Application No. 62/088,509, Attorney Docket Number P103-1PUS, entitled “SYSTEM, METHOD, AND APPARATUS FOR AUTOMATIC MANUFACTURING OF SOLAR PANELS,” filed Dec. 5, 2014; and U.S. Provisional Patent Application No. 62/143,694, Attorney Docket Number P103-2PUS, entitled “SYSTEMS AND METHODS FOR PRECISION AUTOMATION OF MANUFACTURING SOLAR PANELS,” filed Apr. 6, 2015; the disclosures of which are incorporated herein by reference in their entirety for all purposes.

This is also related to U.S. patent application Ser. No. 14/563,867, Attorney Docket Number P67-3NUS, entitled “HIGH EFFICIENCY SOLAR PANEL,” filed Dec. 8, 2014; and U.S. patent application Ser. No. 14/510,008, Attorney Docket Number P67-2NUS, entitled “MODULE FABRICATION OF SOLAR CELLS WITH LOW RESISTIVITY ELECTRODES,” filed Oct. 8, 2014; the disclosures of which are incorporated herein by reference in their entirety for all purposes. This is also related to a co-pending U.S. Patent Application No. TBA, Attorney Docket Number P161-1NUS, entitled “HIGH-EFFICIENCY PV PANEL WITH CONDUCTIVE BACKSHEET,” filed TBA; the disclosures of which are incorporated herein by reference in their entirety for all purposes.

### FIELD OF THE INVENTION

This is generally related to photovoltaic structures. More specifically, this is related to the busbar design of a photovoltaic structure. The specially designed busbar can include additional contact pads to enable electrical access to the photovoltaic structure when the photovoltaic structure is part of a cascaded string.

### DEFINITIONS

“Solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

A “cascade” is a physical arrangement of solar cells or strips that are electrically coupled via electrodes on or near their edges. There are many ways to physically connect adjacent photovoltaic structures. One way is to physically overlap them at or near the edges (e.g., one edge on the positive side and another edge on the negative side) of adjacent structures. This overlapping process is sometimes referred to as “shingling.” Two or more cascading photovoltaic structures or strips can be referred to as a “cascaded string,” or more simply as a string.

“Finger lines,” “finger electrodes,” and “fingers” refer to elongated, electrically conductive (e.g., metallic) electrodes of a photovoltaic structure for collecting carriers.

A “busbar,” “bus line,” or “bus electrode” refers to an elongated, electrically conductive (e.g., metallic) electrode of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or solar cell strip. A photovoltaic structure is not limited to a device fabricated by a particular method. For example, a photovoltaic structure can be a crystalline silicon-based solar cell, a thin film solar cell, an amorphous silicon-based solar cell, a poly-crystalline silicon-based solar cell, or a strip thereof.

### BACKGROUND

Advances in photovoltaic technology, which are used to make solar panels, have helped solar energy gain mass appeal among those wishing to reduce their carbon footprint and decrease their monthly energy costs. However, the panels are typically fabricated manually, which is a time-consuming and error-prone process that makes it costly to mass-produce reliable solar panels.

Solar panels typically include one or more strings of complete photovoltaic structures. Adjacent photovoltaic structures in a string may overlap one another in a cascading arrangement. For example, continuous strings of photovoltaic structures that form a solar panel are described in U.S. patent application Ser. No. 14/510,008, filed Oct. 8, 2014 and entitled “Module Fabrication of Solar Cells with Low Resistivity Electrodes,” the disclosure of which is incorporated herein by reference in its entirety. Producing solar panels with a cascaded cell arrangement can reduce the resistance due to inter-connections between the cells, and can increase the number of photovoltaic structures that can fit into a solar panel.

Moreover, it has been shown that solar panels based on strings of strips cascaded in parallel, which are created by dividing complete photovoltaic structures, provide several advantages, including but not limited to: reduced shading, enablement of bifacial operation, and reduced internal resistance. Detailed descriptions of a solar panel based on cascaded strips can be found in U.S. patent application Ser. No. 14/563,867, entitled “HIGH EFFICIENCY SOLAR PANEL,” filed Dec. 8, 2014, the disclosures of which is incorporated herein by reference in its entirety for all purposes. Conventional inter-string connections, including both serial and parallel connections, can involve cumbersome wirings, which often not only complicates the panel manufacturing process but also leads to extra shading.

In addition to interconnecting strings of photovoltaic structures, forming a solar panel also involves connecting each string or portion of the strings to bypass diodes. The bypass diodes can be used to prevent currents flowing from good photovoltaic structures (photovoltaic structures are well-exposed to sunlight and in normal working condition) to bad photovoltaic structures (photovoltaic structures that are burning out or partially shaded) by providing a current path around the bad cells. Ideally, there would be one bypass diode connected to each photovoltaic structure, but electrical connections can be too complicated and expensive. In most cases, one bypass diode can be used to protect a group of serially connected strips, which can be a string or a portion of a string. However, connecting strings or cascaded strips to bypass diodes can be challenging because the strings do not have exposed busbars, except at the very end of the string. In other words, it can be difficult to access a photovoltaic structure that is in the middle of a string.

### SUMMARY

One embodiment of the invention provides an electrode grid of a photovoltaic structure. The electrode grid can include a plurality of finger lines, an edge busbar positioned near an edge of the photovoltaic structure, and a plurality of contact pads, wherein a respective contact pad is configured in such a way that, when the photovoltaic structure is cascaded with an adjacent photovoltaic structure at the edge, the contact pad is at least partially exposed.

In a variation on the embodiment, the contact pad is a widened portion of the edge busbar.

In a variation on the embodiment, the electrode grid further includes an additional non-edge busbar, and the contact pad can be a widened portion of the additional non-edge busbar.

In a variation on the embodiment, a shape of the contact pad can include a taper. The taper can be straight, parabolic, or curved (e.g., a portion of a circle), or any combination thereof.

In a variation on the embodiment, the photovoltaic structure can be a strip obtained from dividing a square- or pseudo-square-shaped solar cell.

The contact pad may be configured to enable electrical coupling between a bypass diode and the photovoltaic structure, and/or mechanical bonding between the photovoltaic structure and a backsheet.

In one embodiment, the contact pad can be at least twice as wide as the edge busbar.

### BRIEF DESCRIPTION OF THE FIGURES

FIG. 1A shows an exemplary conductive grid pattern on the front surface of a photovoltaic structure.

FIG. 1B shows an exemplary conductive grid pattern on the back surface of a photovoltaic structure.

FIG. 2A shows a string of strips stacked in a cascaded pattern.

FIG. 2B shows the side-view of the string of cascaded strips.

FIG. 3A shows an exemplary conductive grid pattern on the back surface of a photovoltaic structure used for forming cascaded panels, according to an embodiment of the invention.

FIG. 3B shows the three strips that are formed after the photovoltaic structure is cleaved into strips.

FIG. 3C shows the back side of a photovoltaic structure string comprising cascaded strips, according to an embodiment of the invention In the figures, like reference numerals refer to the same figure elements.

FIG. 4A shows an exemplary conductive grid pattern on the back surface of a photovoltaic structure used for forming cascaded panels, according to an embodiment of the invention.

FIG. 4B shows the three strips that are formed after the photovoltaic structure is cleaved into strips.

FIG. 4C shows the back side of a photovoltaic structure string comprising cascaded strips, according to an embodiment of the invention In the figures, like reference numerals refer to the same figure elements.

FIG. 5 shows a cross-sectional view of a photovoltaic structure string, according to an embodiment of the invention.

FIG. 6A shows a cross-sectional view of a string mechanically bonded to the backsheet, according to an embodiment of the invention.

FIG. 6B shows the top view of a string mechanically bonded to the backsheet, according to an embodiment of the invention.

FIG. 7A shows an exemplary conductive grid pattern on the back surface of a photovoltaic structure used for forming cascaded panels, according to an embodiment of the invention.

FIG. 7B shows an exemplary conductive grid pattern on the back surface of a photovoltaic structure used for forming cascaded panels, according to an embodiment of the invention.

FIGS. 8A-8F each shows an exemplary conductive grid pattern on the back surface of a strip, according to an embodiment of the invention.

FIG. 9 shows an exemplary photovoltaic structure fabrication process, according to an embodiment of the invention.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the invention is not limited to the embodiments shown, but is to be accorded the widest scope consistent with the principles and features disclosed herein.

### Overview

Embodiments of the invention provide a novel busbar design for photovoltaic structures. More specifically, the claimed invention provides a solution for electrical access to a photovoltaic structure when the photovoltaic structure is located in the middle of a cascaded string with busbars at both edges being covered by adjacent photovoltaic structures. In some embodiments, specially designed contact pads (which can include exposed electrically conductive areas) can facilitate electrical connections to the photovoltaic structure, in the event of the edge busbars of the photovoltaic structure being inaccessible. The contact pads can include widened areas of the edge busbar, additional non-edge busbars, or a combination of both.

### Solar Panel Based on Cascaded Strips

As described in U.S. patent application Ser. No. 14/563,867, a solar panel can have multiple (such as 3) strings, each string including cascaded strips, connected in parallel. Such a multiple-parallel-string panel configuration can provide the same output voltage with a reduced internal resistance. In general, a cell can be divided into a number of (e.g., n) strips, and a panel can contain a number of strings (the number of strings can be the same as or different from number of strips in the cell). If a string has the same number of strips as the number of regular photovoltaic structures in a conventional single-string panel, the string can output approximately the same voltage as a conventional panel. Multiple strings can be connected in parallel to form a panel. If the number of strings in a panel is the same as the number of strips in the cell, the solar panel can output roughly the same current as a conventional panel. On the other hand, the panel's total internal resistance can be a fraction (e.g., 1/n) of the resistance of a string. Therefore, in general, the greater n is, the lower the total internal resistance of the panel is, and the more power one can extract from the panel. However, a tradeoff is that as n increases, the number of connections required to inter-connect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, conventional silver-paste or aluminum based electrode may require n to be greater than 4, because process of screen printing and firing silver paste onto a cell does not produce ideal resistance between the electrode and underlying photovoltaic structure. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen-printed-silver-paste electrode. Consequently, a smaller n can be used to attain the benefit of reduced panel internal resistance. In some embodiments, n is selected to be three, which is less than the n value generally needed for cells with silver-paste electrodes or other types of electrodes. Correspondingly, two grooves can be scribed on a single cell to allow the cell to be divided to three strips.

In addition to lower contact resistance, electro-plated copper electrodes can also offer better tolerance to micro cracks, which may occur during a cleaving process. Such micro cracks might adversely impact silver-paste-electrode cells. Plated-copper electrode, on the other hand, can preserve the conductivity across the cell surface even if there are micro cracks in the photovoltaic structure. The copper electrode's higher tolerance for micro cracks allows one to use thinner silicon wafers to manufacture cells. As a result, the grooves to be scribed on a cell can be shallower than the grooves scribed on a thicker wafer, which in turn helps increase the throughput of the scribing process. More details on using copper plating to form a low-resistance electrode on a photovoltaic structure are provided in U.S. patent application Ser. No. 13/220,532, entitled “SOLAR CELL WITH ELECTROPLATED GRID,” filed Aug. 29, 2011, the disclosure of which is incorporated herein by reference in its entirety.

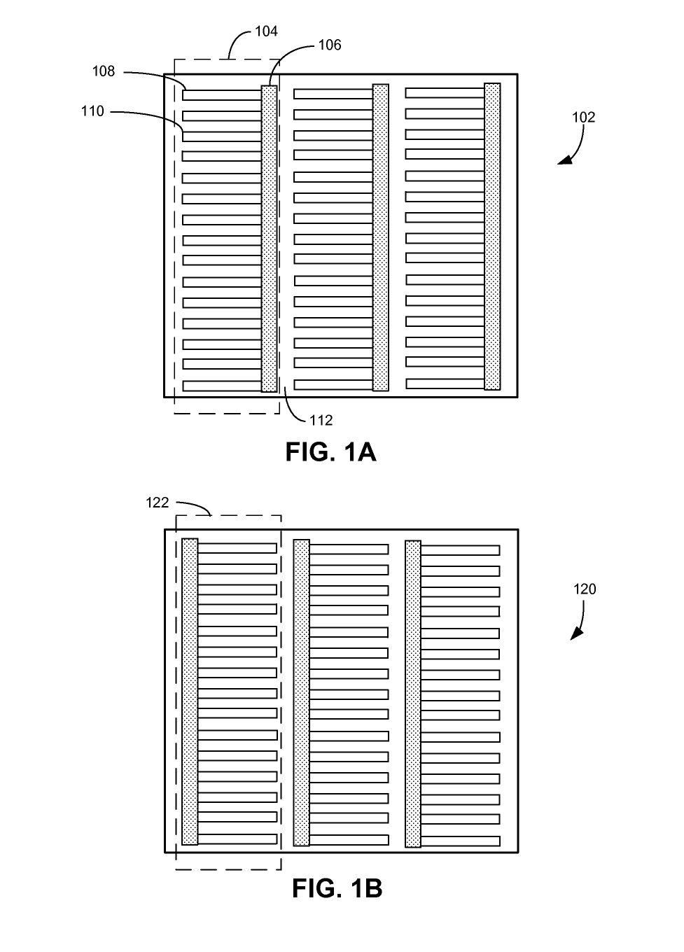

FIG. 1A shows an exemplary grid pattern on the front surface of a photovoltaic structure, according to one embodiment of the present invention. In the example shown in FIG. 1A, grid 102 includes three sub-grids, such as sub-grid 104. This three sub-grid configuration allows the photovoltaic structure to be divided into three strips. To enable cascading, each sub-grid needs to have an edge busbar, which can be located either at or near the edge. In the example shown in FIG. 1A, each sub-grid includes an edge busbar (“edge” here refers to the edge of a respective strip) running along the longer edge of the corresponding strip and a plurality of parallel finger lines running in a direction parallel to the shorter edge of the strip. For example, sub-grid 104 can include edge busbar 106, and a plurality of finger lines, such as finger lines 108 and 110. To facilitate the subsequent laser-assisted scribe-and-cleave process, a predefined blank space (i.e., space not covered by electrodes) is inserted between the adjacent sub-grids. For example, blank space 112 is defined to separate sub-grid 104 from its adjacent sub-grid. In some embodiments, the width of the blank space, such as blank space 112, can be between 0.1 mm and 5 mm, preferably between 0.5 mm and 2 mm. There is a tradeoff between a wider space that leads to more tolerant scribing operation and a narrower space that leads to more effective current collection. In a further embodiment, the width of such a blank space can be approximately 1 mm.

FIG. 1B shows an exemplary grid pattern on the back surface of a photovoltaic structure, according to one embodiment of the invention. In the example shown in FIG. 1B, back grid 120 can include three sub-grids, such as sub-grid 122. To enable cascaded and bifacial operation, the back sub-grid may correspond to the front sub-grid. More specifically, the back edge busbar needs to be located near the opposite edge of the frontside edge busbar. In the examples shown in FIGS. 1A and 1B, the front and back sub-grids have similar patterns except that the front and back edge busbars are located adjacent to opposite edges of the strip. In addition, locations of the blank spaces in back conductive grid 120 correspond to locations of the blank spaces in front conductive grid 102, such that the grid lines do not interfere with the subsequent scribe-and-cleave process. In practice, the finger line patterns on the front and back side of the photovoltaic structure may be the same or different.

In the examples shown in FIGS. 1A and 1B, the finger line patterns can include continuous, non-broken loops. For example, as shown in FIG. 1A, finger lines 108 and 110 both include connected loops with rounded corners. This type of “looped” finger line pattern can reduce the likelihood of the finger lines from peeling away from the photovoltaic structure after a long period of usage. Optionally, the sections where parallel lines are joined can be wider than the rest of the finger lines to provide more durability and prevent peeling. Patterns other than the one shown in FIGS. 1A and 1B, such as un-looped straight lines or loops with different shapes, are also possible.

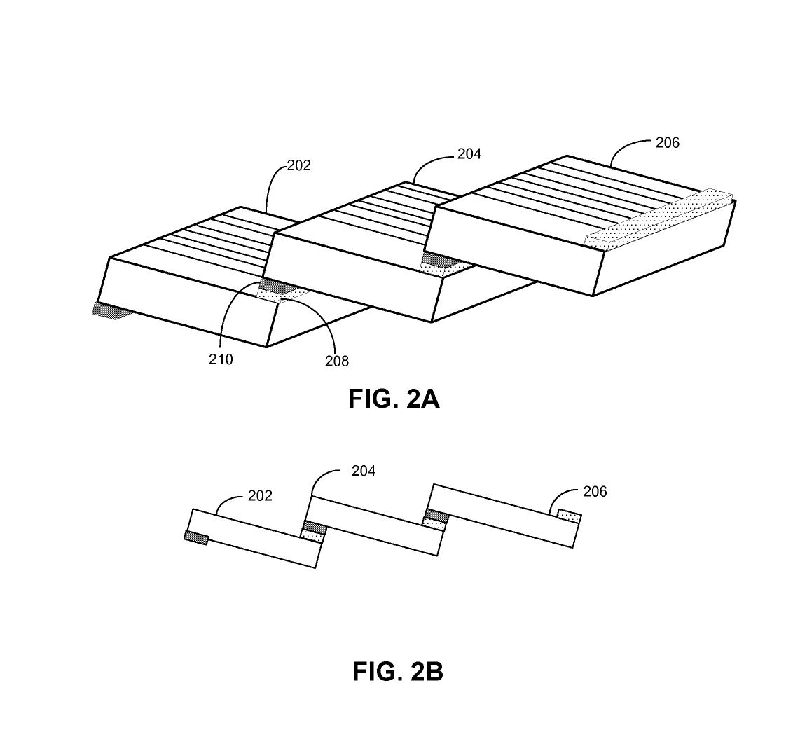

To form a cascaded string, cells or strips (e.g., as a result of a scribing and cleaving process applied to a regular square-shaped cell) can be cascaded with their edges overlapped. FIG. 2A shows a string of cascaded strips, according to an embodiment of the invention. In FIG. 2A, strips 202, 204, and 206 are stacked in such a way that strip 206 partially overlaps adjacent strip 204, which also partially overlaps (on an opposite edge) strip 202. Such a string of strips forms a pattern that is similar to roof shingles. Each strip includes top and bottom edge busbars located at opposite edges of the top and bottom surfaces, respectively. Strips 202 and 204 are coupled to each other via an edge busbar 208 located at the top surface of strip 202 and an edge busbar 210 located at the bottom surface of strip 204. To establish electrical coupling, strips 202 and 204 are placed in such a way that bottom edge busbar 210 is placed on top of and in direct contact with top edge busbar 208.

FIG. 2B shows a side view of the string of cascaded strips, according to one embodiment of the invention. In the example shown in FIGS. 2A and 2B, the strips can be part of a 6-inch square-shaped photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) are placed at the very edge of the strip (as shown in FIGS. 2A and 2B). The same cascaded pattern can extend along an entire row of strips to form a serially connected string.

From FIGS. 2A and 2B one can see that, other than at both ends of a string, all busbars are sandwiched between the overlapped strips. This no-busbar configuration reduces shading. However, hiding the busbars makes it difficult to electrically access the photovoltaic structures, especially the strips that are in the middle of a string. In addition, although a string can be connected to a different string via busbars at either ends of the string, connecting the strings may sometimes require flipping over a string of cascaded strips, which is not an easy task considering that a string may include tens of cascaded strips and the strips are made of fragile Si wafers.

Busbars with Contact Pads

As discussed previously, accessing the middle of a string can be important, especially if one wants to provide bypass protection at a higher granularity than an individual string. For example, to provide bypass protection to half of the strips within a string, one may need to connect a bypass diode in parallel to the half string; that is, electrically couple to a strip in the middle of the string. However, as shown in FIGS. 2A and 2B, there are no exposed busbars on strips in the middle of the string. The finger lines, on the other hand, are too thin to enable electrical connections. To solve this problem, additional contact pads (sometimes also called “landing pads”) that are not blocked by edges of the photovoltaic structures can be provided. However, because additional contact pads can add shading, these additional pads can be placed on the back side (the side that faces away from the majority of the incident light) of the photovoltaic structures.

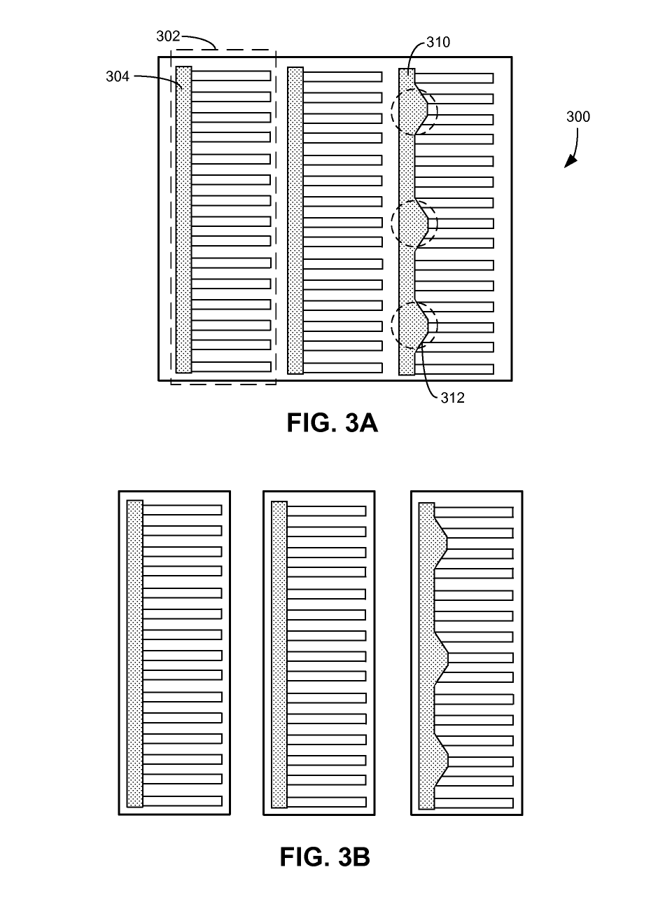

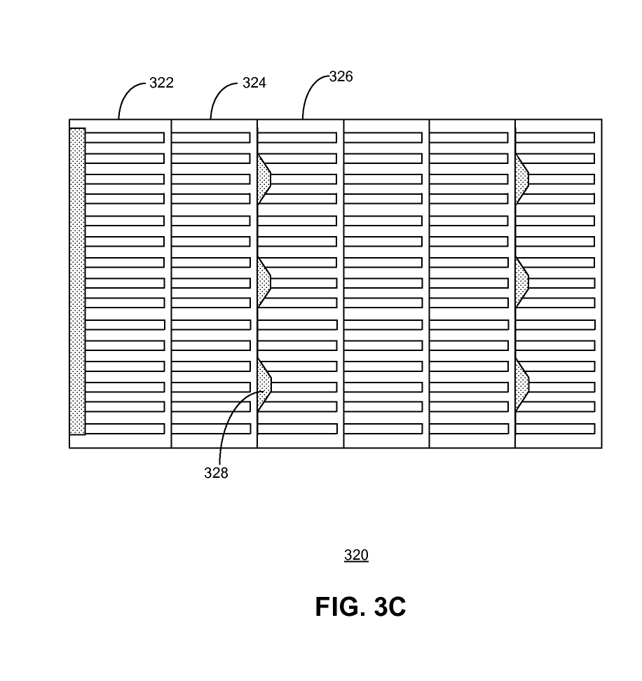

One type of contact pad can be built on existing edge busbars. More specifically, an edge busbar may include areas that are wide enough to be partially exposed after cascading. FIG. 3A shows an exemplary conductive grid pattern on the back surface of a photovoltaic structure, according to an embodiment of the invention. Similar to conductive grid 120 shown in FIG. 1B, conductive grid 300 can include a number of sub-grids with each sub-grid including an edge busbar. For example, sub-grid 302 includes edge busbar 304. In addition to the regular rectangular busbars shown in FIG. 1B, one of the edge busbars can include areas that are widened. For example, edge busbar 310 includes a number of widened areas, as indicated by the dashed circles, such as widened area 312. In some embodiments, the widened areas may have a width that can be at least twice the width of the un-widened portions of the busbar. For example, if the width of a regular busbar (such as busbars shown in FIG. 1B) is about 1.5 mm, the width of the widened areas, such as widened area 312, can be at least 3 mm. The length of widened areas can be somewhat arbitrary, as long as the widened areas are wide enough to prevent overflow of subsequently deposited conductive paste. In some embodiments, the widened areas can be a square. From FIG. 3A, one can also see that the widening is tapered, which can reduce the current crowding effect. The conductive grid pattern on the front (light-facing) surface of the photovoltaic structure remains similar to the one shown in FIG. 1A.

In addition to the straight tapers shown in FIG. 3A, other types of tapers, such as parabolic tapers or arc tapers (i.e., tapers that are part of a circle) can also be used. FIG. 3B shows the three strips that are formed after the photovoltaic structure is cleaved into strips. As shown in FIG. 3B, the three strips can have different grid patterns with one strip (i.e., the rightmost strip) including the specially designed landing pads.

FIG. 3C shows the back side of a string comprising cascaded strips, according to an embodiment of the invention. In FIG. 3C, string 320 includes a number of cascaded strips, such as strips 322, 324, and 326. When the strips are cascaded, the edges of the strips overlap with the bottom busbar of one strip stacked against (or cascaded with) the top busbar of an adjacent strip. As a result, when viewed from the back side, the edge busbar of strip 324 is not visible. On the other hand, the edge busbar of strip 326 includes widened areas, such as widened area 328, which are still exposed after the strip edge is stacked against the neighboring strip.

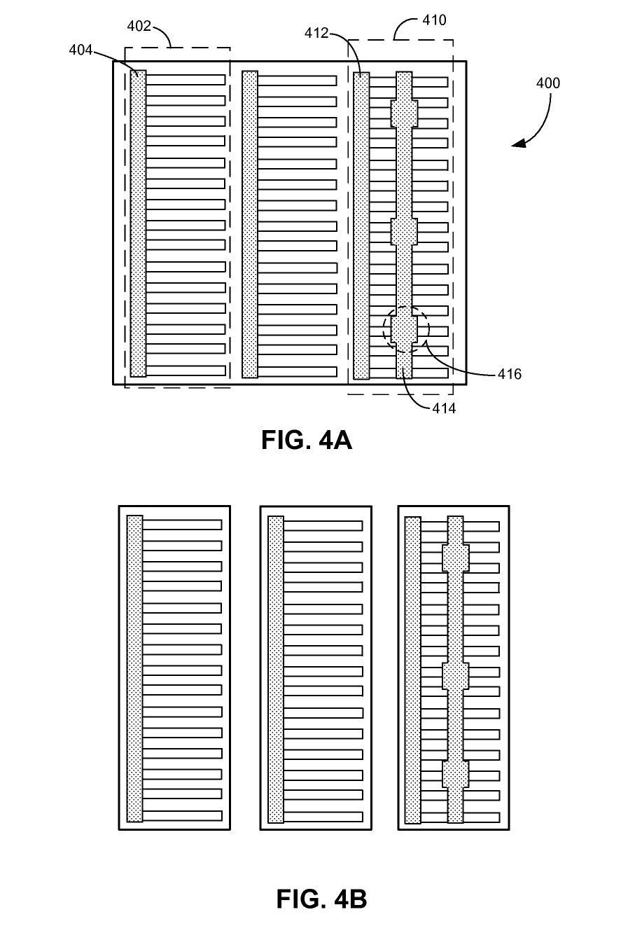

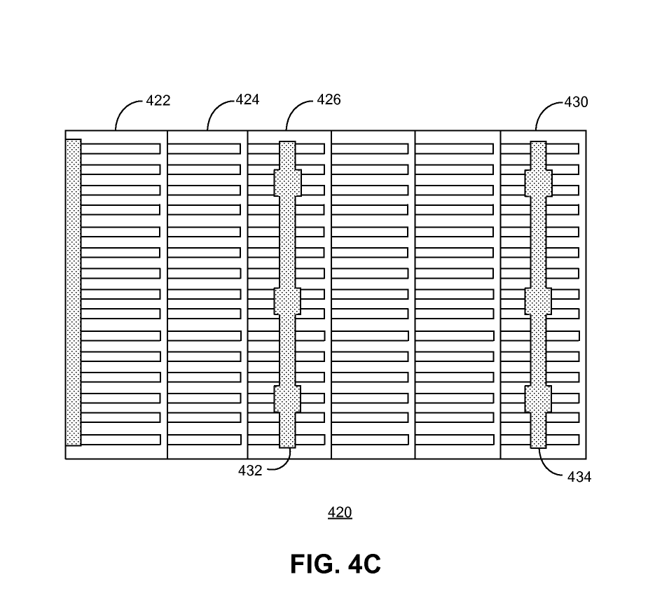

Besides widening existing busbars, one may also add additional busbars at the back side of the photovoltaic structure to form contact pads. FIG. 4A shows an exemplary conductive grid pattern on the back surface of a photovoltaic structure, according to an embodiment of the invention. Similar to conductive grid 300 shown in FIG. 3A, conductive grid 400 includes a number of sub-grids with each sub-grid including an edge busbar. For example, sub-grid 402 includes an edge busbar 404. In addition, one of the sub-grids of conductive grid 400 can include an additional non-edge busbar. In the example shown in FIG. 4A, in addition to edge busbar 412, sub-grid 410 can also include additional busbar 414 located within (e.g., in the middle of) sub-grid 410. The additional busbar can also include widened areas, which can act as contact pads to couple to vias formed at corresponding locations in the backsheet. For example, additional busbar 414 can include three widened areas, such as widened area 416. In some embodiments, the width of the widened areas can be at least twice as wide as the regular busbar. For example, if the width of a regular busbar (such as edge busbar 404) is about 1.5 mm, the width of the widened areas in the additional busbar, such as widened area 416, can be at least 3 mm. In some embodiments, the widening can also be tapered to reduce the current crowding effect. The conductive grid pattern on the front (light-facing) surface of the photovoltaic structure can remain similar to the one shown in FIG. 1A. FIG. 4B shows the three strips that are formed after the photovoltaic structure is cleaved into strips.

FIG. 4C shows the back side of a string comprising cascaded strips, according to an embodiment of the invention. In FIG. 4C, string 420 includes a number of cascaded strips, such as strips 422, 424, and 426. As shown in FIG. 4C, when the strips are stacked in a cascaded manner, the edge busbars are stacked against other edge busbars and will no longer be visible. On the other hand, additional busbars, such as busbars 432 and 434, which are located in the middle of the sub-grids, will be exposed.

In the example shown in FIGS. 4B and 4C, additional busbars can be located approximately in the center of every third strip, given that the photovoltaic structure of a regular size is divided into three strips. However, in practice, these additional busbars can also be placed at any arbitrary locations, as long as they can be at least partially exposed after the strips are stacked in a cascaded manner. For example, instead of being located on the edge strip of an undivided structure, such as strip 426 or 430, the additional busbar can also be placed on the middle strip, such as strip 424, or be placed on two of the three strips. In addition, the additional busbars can be placed at locations that are off to the side (either on the same side of the bottom edge busbar or on its opposite side) of the strips, as long as the stacking of the edges does not block access to the contact pads.

These exposed contact pads, which can be formed by widening existing edge busbars or adding additional busbars, can enable electrical connections to the back side of certain strips, even when such strips are sandwiched within the string. More specifically, when a conductive backsheet (i.e., a backsheet with a conductive interlayer) is used, one can establish a conductive path between these contact pads and the conductive interlayer in the backsheet through conductive paste filled in the vias created underneath the landing pads. Such a conductive path can then be used for connecting a bypass diode to a portion of the string. For example, a bypass diode can be connected in parallel to a portion of string 420 that starts from strip 430 and ends at strip 426. To do so, one polarity of the diode can be coupled to the frontside busbar of strip 430, while the other polarity of the diode can be coupled to exposed additional busbar 432. As a result, any malfunction of any strip between strips 426 and 430 can turn on the bypass diode. Detailed descriptions of the conductive backsheet can be found in co-pending application number TBA, Attorney Docket Number P161-1NUS, entitled “HIGH-EFFICIENCY PV PANEL WITH CONDUCTIVE BACKSHEET,” filed XXXX XX, 2015, the disclosures of which is incorporated herein by reference in its entirety for all purposes.

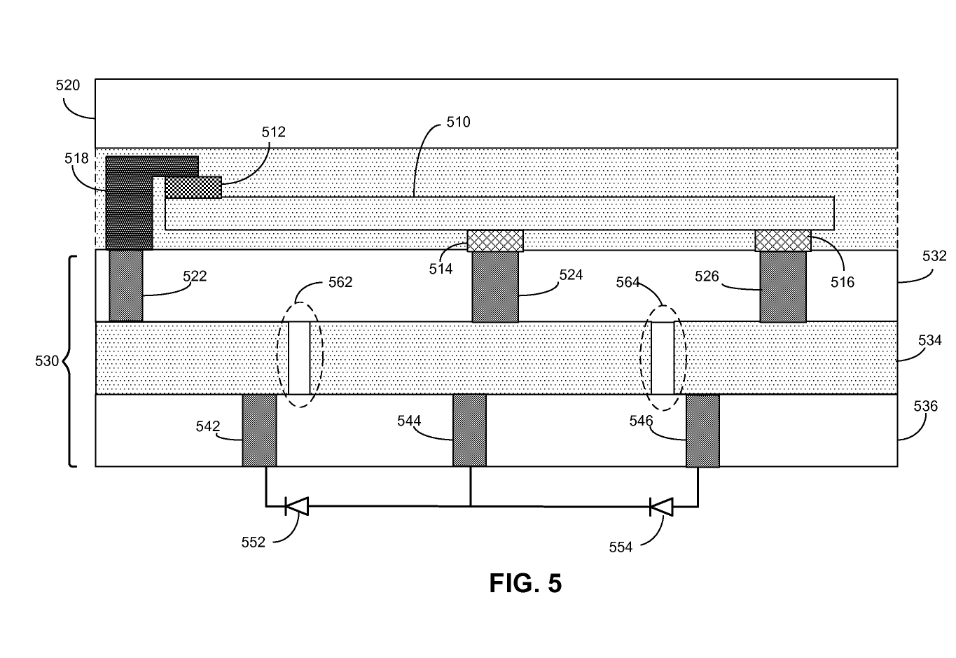

FIG. 5 shows a cross-sectional view of a string, according to an embodiment of the invention. In FIG. 5, string 510 can be sandwiched between glass cover 520 and backsheet 530, and includes top busbar 512, contact pad 514, and bottom busbar 516. Top busbar 512 can be coupled to conductive tab 518, which can facilitate electrical coupling to top busbar 512 from the bottom side of string 510. Backsheet 530 can include top insulation layer 532, conductive interlayer 534, and bottom insulation layer 536. Top insulation layer 532 includes vias 522, 524, and 526, which are positioned underneath conductive tab 518, contact pad 514, and bottom busbar 516, respectively. These vias can be filled with conductive paste to facilitate electrical connections to top busbar 512, contact pad 514, and bottom busbar 516. Gaps 562 and 564 within conductive interlayer 534 can ensure that top busbar 512, contact pad 514, and bottom busbar 516 are not shorted to each other.

In some embodiments, bypass-diodes can be located outside of the solar panel, e.g., behind the backsheet. To electrically connect the bypass diodes to the strings, vias can also be created within bottom insulation layer 536, such as vias 542, 544, and 546. In the example shown in FIG. 5, the two different polarities of bypass diode 552 are electrically coupled to top busbar 512 and contact pad 514 through vias 542 and 544, respectively. Similarly, the two different polarities of bypass diode 554 can be electrically coupled to contact pad 514 and bottom busbar 516 through vias 544 and 546, respectively. As a result, bypass diode 552 can provide bypass protection to the left portion (the portion between top busbar 512 and contact pad 514) of string 510, and bypass diode 554 can provide bypass protection to the right portion (the potion between contact pad 514 and bottom busbar 516) of string 510, thus achieving sub-string level bypass protections. Although FIG. 5 shows that two bypass diodes are used to bypass protect a single string, in practice, more or fewer bypass diodes can be used to provide bypass protections to the single string.

In addition to enabling sub-string level bypass protections, these contact/landing pads can also facilitate mechanical bonding between the string and the backsheet. Because a string can include tens of strips, mechanically bonding one or more middle strips within a string to the backsheet can reduce the risk of position shift or fracturing when the string is handled during subsequent fabrication operations. In some embodiments, one can apply adhesive paste onto these contact/landing pads to mechanically bond the corresponding strips to the backsheet. When a conductive backsheet is used, locations of the vias in the top insulation layer of the backsheet can correspond to the locations of the contact/landing pads. The conductive interlayer can also be patterned accordingly to the designed purpose of the contact/landing pads. If the contact/landing pads are functioned as electrical contacts, the conductive interlayer will be patterned based on the desired path of conductivity. On the other hand, if the contact/landing pads are used for bonding purposes only (in such cases, they are often referred to as landing pads), the conductive interlayer surrounding such landing pads may need to be electrically insulated from other conductive portions of the back sheet in order to prevent unwanted electrical coupling.

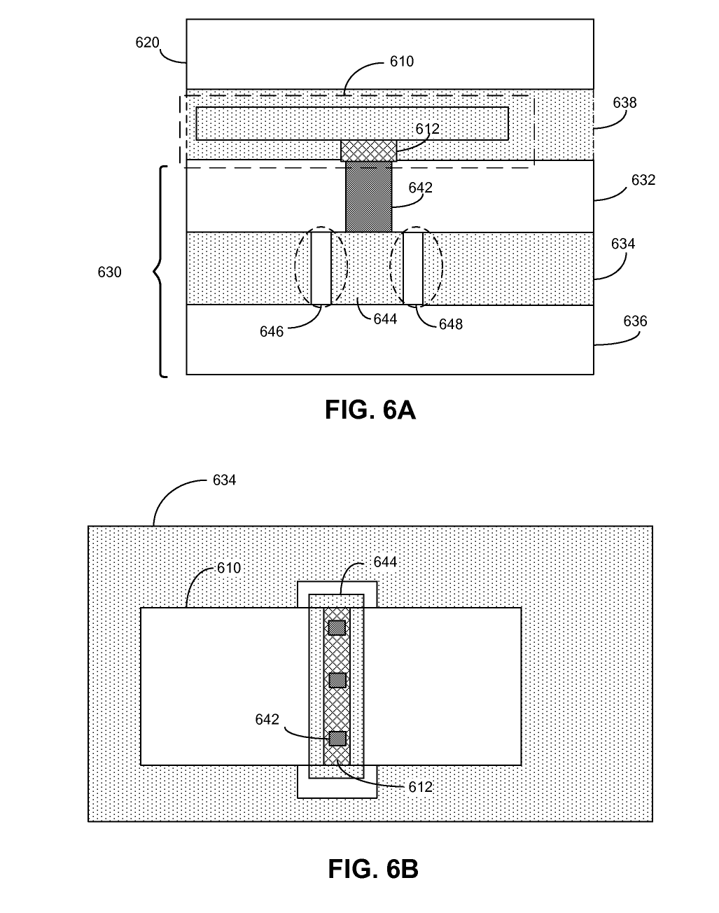

FIG. 6A shows a cross-sectional view of a string mechanically bonded to the backsheet, according to an embodiment of the invention. In FIG. 6A, string 610 is positioned between front cover 620 and backsheet 630. Backsheet 630 can include top insulation layer 632, conductive interlayer 634, and bottom insulation layer 636. Backsheet 630 may optionally include sealant layer 638. For simplicity, FIG. 6A only shows one additional busbar 612 acting as a landing pad located in the middle of string 610, and does not show the edge busbars.

To facilitate mechanical bonding between string 610 and backsheet 630, via 642 can be created in top insulation layer 632 directly underneath additional busbar 612. By filling via 642 with adhesives (which can include conductive adhesive paste or other insulating adhesive paste), one can mechanically bond string 610 to backsheet 630. More specifically, the adhesives bond string 610 to conductive interlayer 634. Since the adhesives most likely include conductive paste (to keep the paste application process consistent throughout the panel production), to prevent undesired electrical coupling, conductive portion 644 that is in contact with the conductive paste is insulated from the rest of conductive interlayer 634 via gaps 646 and 648. As a result, adhesives within via 642 merely serve the purpose of establishing mechanical bonding, and do not provide any electrical coupling to other circuitries.

FIG. 6B shows the top view of a string mechanically bonded to the backsheet, according to an embodiment of the invention. For purposes of illustration, the different layers are overlaid on each other in a transparent manner, although they are not transparent. The vertical sequence of the layers can be seen in FIG. 6A. As shown in FIG. 6B, a number of vias, such as via 642, are created under additional busbar 612 of string 610. Adhesive paste filled in these vias couples string 610 to portion 644 within conductive interlayer 634. Because portion 644 is carved out from the rest of conductive interlayer 634, no electrical coupling to additional busbar 612 will be established through portion 644. The examples shown in FIGS. 6A and 6B can also be applied to scenarios where the landing pads are widened areas of the edge busbars.

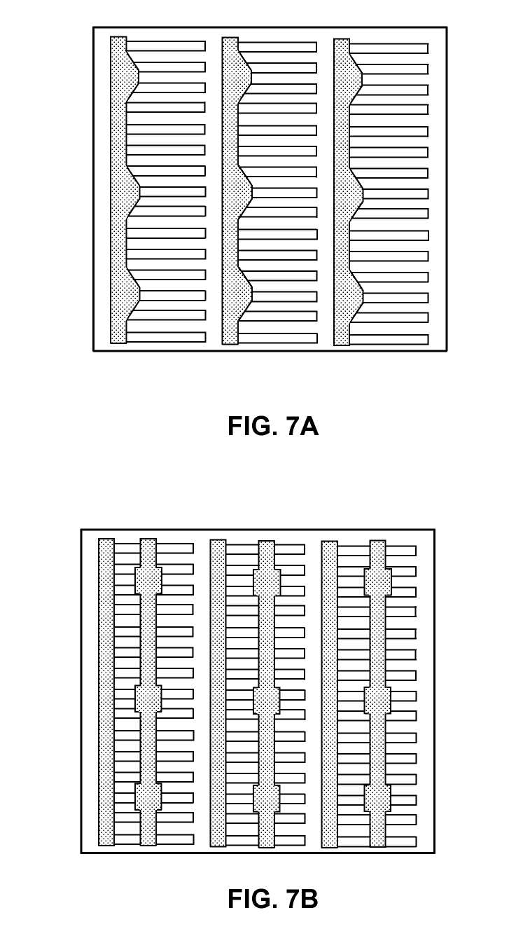

Although it is also possible to widen the edge busbar of every strip, or to add an additional back busbar on every strip, which can enable electrical access to every strip within the string (as shown in FIGS. 7A and 7B), in most cases, such a high granularity is not necessary and wasteful. As described previously, the conductive grid, including busbars and finger lines, can include electro- or electroless-plated Cu layer. Widening existing busbars or adding more busbars requires more Cu to be consumed, thus increasing the panel fabrication cost.

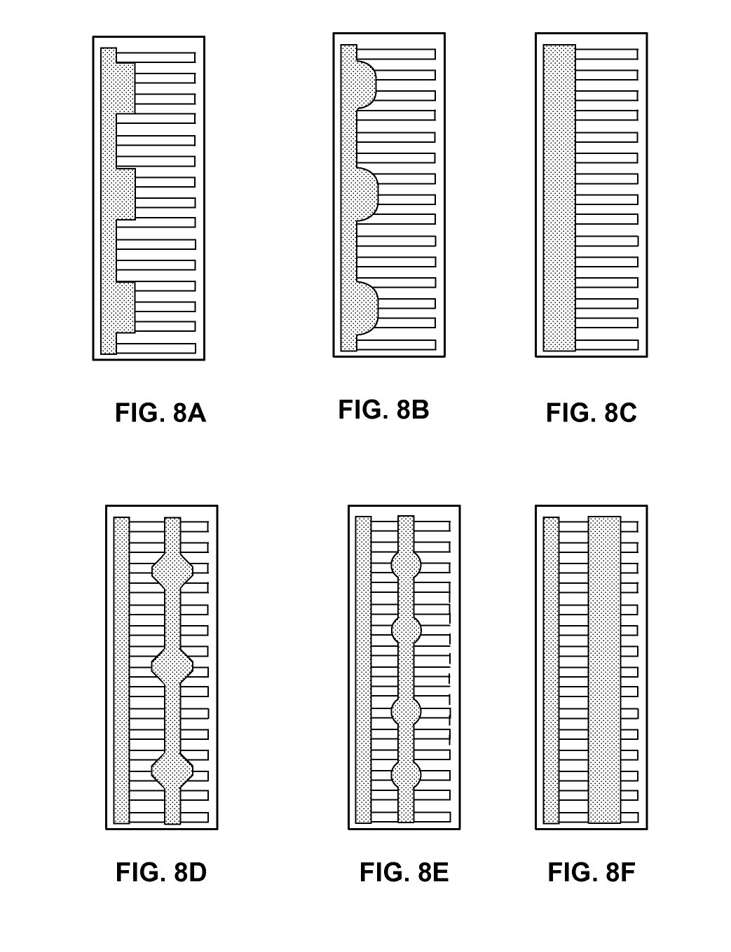

Other than the ones shown in FIGS. 7A and 7B, the contact/landing pads can have other forms or shapes. For exemplary purposes, FIGS. 8A-8F show various forms of contact/landing pads. In the example shown in FIG. 8A, the contact/landing pads include widened, un-tapered areas of an edge busbar. In the example shown in FIG. 8B, the contact/landing pads can include widened, tapered areas of an edge busbar. The tapering can be curved, which can be parabolic or part of a circle. In the example shown in FIG. 8C, the entire edge busbar is widened to allow it to be partially exposed when the strip is edge stacked. Hence, the contact/landing pad can include the widened portion of the entire edge busbar. However, such a design can lead to the increased Cu consumption, and can lead to increased manufacture cost. In the example shown in FIG. 8D, the contact/landing pads can include widened areas of an additional busbar located in the middle of the strip. The widened areas can include straight tapers. In the example shown in FIG. 8E, the contact/landing pads can include widened areas of an additional busbar located in the middle of the strip. In the example shown in FIG. 8F, the contact/landing pads can include an additional busbar located in the middle of the strip. This entire additional busbar is widened. Similar to the example shown in FIG. 8C, this design can lead to increased manufacture cost. In addition to the shape difference, the number of contact/landing pads on each busbar (either the edge busbar or the additional busbar) can also be different. In the examples shown in FIGS. 8A-8B and 8D, there are three contact/landing pads per busbar. On the other hand, in the example shown in FIG. 8E, the additional busbar includes four landing pads.

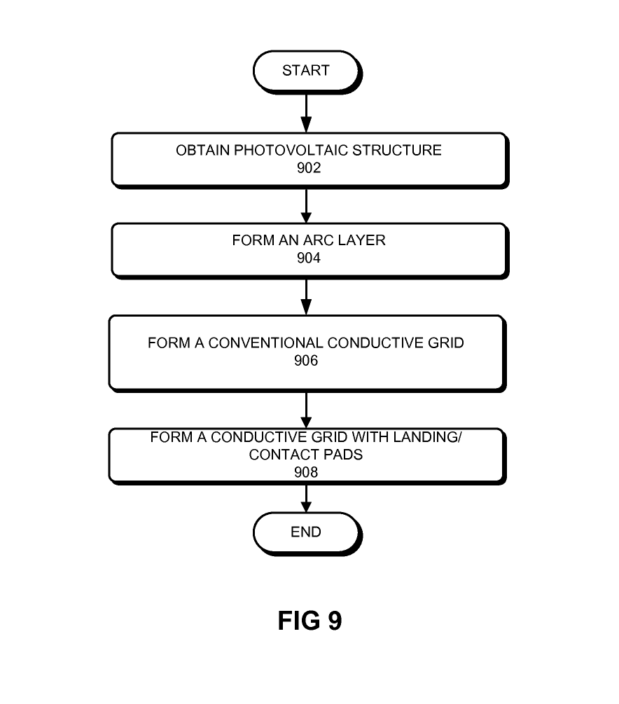

Fabrication process for the photovoltaic structure with a conductive grid that includes the contact/landing pads can be similar to the fabrication process used for forming regular cascaded photovoltaic structures, except that special mask that defines the contact/landing pads is used instead of a conventional mask. FIG. 9 shows an exemplary photovoltaic structure fabrication process, according to an embodiment of the invention. In operation 902, a photovoltaic structure that includes a base layer, an emitter layer, and a surface field layer is prepared. An anti-reflection coating (ARC) can be formed on the light-facing side of the photovoltaic structure (operation 904). For bifacial photovoltaic structures, an ARC layer is form on each side. The ARC layer can include one or more of: SiOₓ, SiNₓ, and various transparent conductive oxide (TCO) materials. A conventional conductive grid with an edge busbar can be formed on the light-facing side of the photovoltaic structure (operation 906). A conductive grid with contact/landing pads can be formed on the side of the photovoltaic structure that faces away from the light (operation 908). Both conductive grids can include plated metals, such as electrical plated Cu. In some embodiments, forming the conductive grid can also involve depositing, using a physical vapor deposition (PVD) technique one or more metal adhesive/seed layers prior to the electrical plating process to enhance adhesion between the plated metal and the underneath layers, which can be the ARC layer or the semiconductor emitter/surface field layer.

The foregoing descriptions of various embodiments have been presented only for purposes of illustration and description. They are not intended to be exhaustive or to limit the invention to the forms disclosed. Accordingly, many modifications and variations will be apparent to practitioners skilled in the art. Additionally, the above disclosure is not intended to limit the invention.

What is claimed is:

1. An electrode grid of a photovoltaic structure, comprising:
a plurality of finger lines;
an edge busbar positioned near an edge of the photovoltaic structure; and
a plurality of contact pads, wherein a respective contact pad is configured in such a way that, when the photovoltaic structure is cascaded with an adjacent photovoltaic structure at the edge, the contact pad is at least partially exposed.

2. The electrode grid of claim 1, wherein the contact pad is a widened portion of the edge busbar.

3. The electrode grid of claim 1, further comprising an additional non-edge busbar, wherein the contact pad is a widened portion of the additional non-edge busbar.

4. The electrode grid of claim 1, wherein a shape of the contact pad comprises a taper.

5. The electrode grid of claim 4, wherein the taper is selected from a group consisting of:
a straight taper;
a parabolic taper;
a curved taper; or
a combination thereof.

6. The electrode grid of claim 1, wherein the photovoltaic structure is a strip obtained from dividing a square- or pseudo-square-shaped solar cell.

7. The electrode grid of claim 1, wherein the contact pad is configured to enable electrical coupling between a bypass diode and the photovoltaic structure.

8. The electrode grid of claim 1, wherein the contact pad is configured to facilitate mechanical bonding between the photovoltaic structure and a backsheet.

9. The electrode grid of claim 1, wherein the contact pad is at least twice as wide as the edge busbar.

10. A photovoltaic structure, comprising:
a semiconductor multilayer structure;
a first metal grid positioned on a first side of the multilayer structure, wherein the first metal grid includes a first busbar positioned near a first edge; and
a second metal grid positioned on a second side of the multilayer structure, wherein the second metal grid includes:
a second busbar positioned near a second edge opposite to the first edge; and
a number of contact pads, wherein a respective contact pad is configured in such a way that, when the photovoltaic structure is cascaded with an adjacent photovoltaic structure at the second edge, the contact pad is at least partially exposed.

11. The photovoltaic structure of claim 10, wherein the contact pad is at least partially overlapped with the second busbar.

12. The photovoltaic structure of claim 10, further comprising an additional non-edge busbar positioned on the second side of the multilayer structure, wherein the contact pad is at least partially overlapped with the additional non-edge busbar.

13. The photovoltaic structure of claim 10, wherein a shape of the contact pad comprises a taper.

14. The photovoltaic structure of claim 10, wherein the contact pad is configured to enable electrical coupling between a bypass diode and the photovoltaic structure.

15. The photovoltaic structure of claim 10, wherein the contact pad is configured to facilitate mechanical bonding between the photovoltaic structure and a backsheet.

16. The photovoltaic structure of claim 10, wherein the contact pad is at least twice as wide as the second busbar.

17. An electrode grid of a photovoltaic structure, comprising:
a number of sub-grids each comprising an edge busbar and a number of finger lines, wherein adjacent sub-grids are separated by a blank space, wherein at least one sub-grid includes a number of contact pads, and wherein a respective contact pad is at least twice as wide as the edge busbar.

18. The electrode grid of claim 17, wherein the contact pad is at least partially overlapped with a corresponding edge busbar of the sub-grid.

19. The electrode grid of claim 17, wherein the sub-grid further comprises an additional non-edge busbar, and wherein the contact pad is at least partially overlapped with the additional non-edge busbar.

20. The electrode grid of claim 17, wherein the contact pad is tapered.
